(19) United States
(12) Patent Application Publication
(10) Pub. No.: US 2024/0283405 A1
(43) Pub. Date: Aug. 22, 2024

(54) BIAS VOLTAGE GENERATING CIRCUIT

(71) Applicant: Realtek Semiconductor Corp., HsinChu (TW)

(72) Inventor: Po-Chih Wang, HsinChu (TW)

(73) Assignee: Realtek Semiconductor Corp., HsinChu (TW)

(21) Appl. No.: 18/420,711

(22) Filed: Jan. 23, 2024

(30) Foreign Application Priority Data
Feb. 21, 2023 (TW) 112106286

(51) Int. Cl. H03F 1/02; H03F 3/21

(52) U.S. Cl. CPC H03F 1/0205; H03F 3/21

(57) ABSTRACT

A bias voltage generating circuit includes a first circuit subunit, a second circuit subunit, and a third circuit subunit. The first circuit subunit is arranged to generate a first bias voltage at a first node in response to a first current and a first input voltage. The second circuit subunit is coupled to the first circuit subunit, and is arranged to receive the first bias voltage and generate a second current flowing through a second node, wherein the second current is mirrored from the first current. The third circuit subunit is coupled to the second node, and is arranged to generate a second bias voltage at a third node in response to the second current and a second input voltage.

### BACKGROUND OF THE INVENTION

### 1. Field of the Invention

The present invention is related to a bias voltage generating circuit, and more particularly, to a bias voltage generating circuit arranged to generate a stable bias voltage for a power amplifier circuit.

### 2. Description of the Prior Art

Amplifier circuits are used to increase signal output power in communication systems. The amplifier circuit operates by obtaining power from a power supply, and controlling a waveform of an output signal to be consistent with that of an input signal in order to increase amplitude of the output signal. The amplifier circuit design requires a trade-off between power consumption and linearity, wherein non-linear amplifier circuits usually have higher power amplifier efficiency (PAE), and linear amplifier circuits usually have a lower PAE.

Appropriate bias voltage design could help the amplifier circuit achieve a better balance between linearity and amplification efficiency. In addition, if a DC current of the amplifier circuit could be accurately controlled, the power consumption of the amplifier circuit could also be effectively adjusted, resulting in similar performance in chips implementing the same amplifier circuit. As a result, how to generate a stable bias voltage and a precise DC current used by the power amplifier circuit is a topic worthy of attention in the field of amplifier circuit design.

### SUMMARY OF THE INVENTION

It is therefore one of the objectives of the present invention to provide a bias voltage generating circuit that can generate a stable bias voltage and a precise DC current for a power amplifier circuit.

According to an embodiment of the present invention, a bias voltage generating circuit is provided. The bias voltage generating circuit comprises a first circuit subunit, a second circuit subunit, and a third circuit subunit. The first circuit subunit is arranged to generate a first bias voltage at a first node in response to a first current and a first input voltage. The second circuit subunit is coupled to the first circuit subunit, and is arranged to receive the first bias voltage and generate a second current flowing through a second node, wherein the second current is mirrored from the first current. The third circuit subunit is coupled to the second node, and is arranged to generate a second bias voltage at a third node in response to the second current and a second input voltage.

According to another embodiment of the present invention, a bias voltage generating circuit is provided. The bias voltage generating circuit comprises a first circuit subunit, a second circuit subunit, and a third circuit subunit. The first circuit subunit is arranged to generate a first bias voltage at a first node in response to a first current and a first input voltage. The second circuit subunit is coupled to the first circuit subunit, and is arranged to receive the first bias voltage and generate a second current flowing through a second node, wherein the second current is mirrored from the first current. The third circuit subunit is coupled to the second node, and is arranged to generate a second bias voltage at a third node in response to the second current and a second input voltage. The first node is further coupled to a first bias voltage input terminal of a power amplifier circuit, and is arranged to provide the first bias voltage to the power amplifier circuit. The third node is further coupled to a second bias voltage input terminal of the power amplifier circuit, and is arranged to provide the second bias voltage to the power amplifier circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a bias voltage generating circuit according to a first embodiment of the present invention.

FIG. 2 is a diagram illustrating a bias voltage generating circuit according to a second embodiment of the present invention.

FIG. 3 is a diagram illustrating a power amplifier circuit according to an embodiment of the present invention.

### DETAILED DESCRIPTION

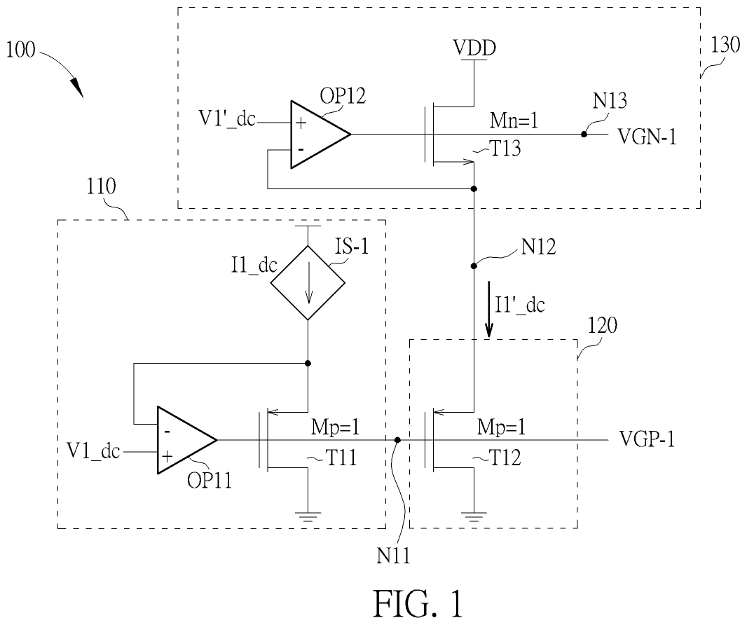

FIG. 1 is a diagram illustrating a bias voltage generating circuit 100 according to a first embodiment of the present invention. The bias voltage generating circuit 100 includes a first circuit subunit 110, a second circuit subunit 120, and a third circuit subunit 130. The first circuit subunit 110 generates a bias voltage VGP-1 in response to a current I1_dc and an input voltage V1_dc. The second circuit subunit 120 is coupled to the first circuit subunit 110, and receives the bias voltage VGP-1 and generates a current I1′_dc flowing through a node N12, wherein the current I1′_dc is mirrored from the current I1_dc. The third circuit subunit 130 is coupled to the node N12, and generates a bias voltage VGN-1 at a node N13 in response to the current I1′_dc and an input voltage V1′_dc .

The first circuit subunit 110 includes an amplifier circuit OP11, a transistor T11, and a current source IS-1. The amplifier circuit OP11 has a non-inverting input terminal, an inverting input terminal, and an output terminal, wherein the non-inverting input terminal of the amplifier circuit OP11 receives the input voltage V1_dc. The transistor T11 has a first terminal coupled to the output terminal of the amplifier circuit OP11, a second terminal coupled to the inverting input terminal of the amplifier circuit OP11, and a third terminal coupled to a first voltage source. The transistor T11 may be a P-type metal oxide semiconductor field effect transistor (MOSFET), wherein the first terminal of the transistor T11 may be a gate terminal of the P-type MOSFET, the second terminal of the transistor T11 may be a source terminal of the P-type MOSFET, and the third terminal of the transistor T11 may be a drain terminal of the P-type MOSFET. The first voltage source may be a voltage source providing a grounding voltage. The current source IS-1 may be arranged to provide the current I1_dc.

The gate terminal of the transistor T11 is coupled to both the output terminal of the amplifier circuit OP11 and a node N11, and the node N11 is further coupled to the second circuit subunit 120.

Assume that the amplifier circuit OP11 has a very large gain, and a relationship between the non-inverting terminal and the inverting terminal of the amplifier circuit OP11 is a virtual ground. As a result, a voltage at the inverting input terminal of the amplifier circuit OP11 is a voltage generated at the second terminal (e.g. the source terminal) of the transistor T11 in response to the current I1_dc and the input voltage V1_dc, and is equal to or substantially equal to the input voltage V1_dc.

The second circuit subunit 120 includes a transistor T12. The transistor T12 includes a first terminal coupled to the output terminal of the amplifier circuit OP11, a second terminal coupled to the node N12, and a third terminal coupled to the first voltage source. The transistor T12 may be a P-type MOSFET, wherein the first terminal of the transistor T12 may be a gate terminal of the P-type MOSFET, the second terminal of the transistor T12 may be a source terminal of the P-type MOSFET, and the third terminal of the transistor T12 may be a drain terminal of the P-type MOSFET. The first terminal of the transistor T12 is coupled to the first terminal of the transistor T11, and may be further coupled to the output terminal of the amplifier circuit OP11 and the node N11. In this embodiment, both the transistors T11 and T12 may be designed to have the same width (e.g. Mp=1), and the gate voltage and the drain voltage of the transistor T11 are the same as that of the transistor T12. As a result, the current I1′_dc flowing through the transistor T12 is a mirror current of the current I1_dc, and a current amplitude of the current I1′_dc is equal to or substantially equal to that of the current I1_dc.

The third circuit subunit 130 includes an amplifier circuit OP12 and a transistor T13. The amplifier circuit OP12 has a non-inverting input terminal, an inverting input terminal, and an output terminal, wherein the non-inverting input terminal of the amplifier circuit OP12 receives the input voltage V1′_dc. The transistor T13 has a first terminal coupled to the output terminal of the amplifier circuit OP12, a second terminal coupled to the inverting input terminal of the amplifier circuit OP12, and a third terminal coupled to a second voltage source. The transistor T13 may be an N-type MOSFET, wherein the first terminal of the transistor T13 may be a gate terminal of the N-type MOSFET, the second terminal of the transistor T13 may be a source terminal of the N-type MOSFET, and the third terminal of the transistor T13 may be a drain terminal of the N-type MOSFET. The second voltage source may be a voltage source providing a voltage VDD. The second terminal of the transistor T13 is coupled to the node N12. The first terminal of the transistor T13 is coupled to the node N13 for providing the bias voltage VGN-1.

Assume that the amplifier circuit OP12 has a very large gain, and a relationship between the non-inverting terminal and the inverting terminal of the amplifier circuit OP12 is a virtual ground. As a result, a voltage at the inverting input terminal of the amplifier circuit OP12 is equal to or substantially equal to the input voltage V1′_dc. For example, each of the amplifier circuits OP11 and OP12 may be an operational amplifier.

The input voltage V1_dc received by the first circuit subunit 110 may be the same as the input voltage V1′_dc received by the third circuit subunit 130. In addition, the current I1_dc provided by the current source IS-1 is generated through a bandgap circuit. As a result, the current I1_dc is a precise DC current.

The first circuit subunit 110 may be arranged to establish the stable current I1_dc at the second terminal of the transistor T11, and mirror the current I1_dc to the second circuit subunit 120. Since both the transistor T12 of the second circuit subunit 120 and the transistor T13 of the third circuit subunit 130 are coupled to the node N12, the mirrored current I1′_dc flows through the transistors T12 and T13. In addition, the bias voltage generating circuit 100 provides the bias voltages VGP-1 and VGN-1 to a power amplifier circuit (not shown in FIG. 1) through the nodes N11 and N13, respectively, for acting as bias voltage inputs and therefore providing stable bias voltages to the power amplifier circuit. Due to the stable voltages, another stable current may be mirrored within the power amplifier circuit in response to the current I1′_dc flowing through the transistors T12 and T13, and a current amplitude of the current inside the power amplifier circuit may be a multiple of the current I1′_dc, thereby generating the precise DC current required by the power amplifier circuit.

It should be noted that the transistor type shown in FIG. 1 is not a limitation of the present invention. In some embodiments, the present invention can establish a stable DC current through N-type transistors.

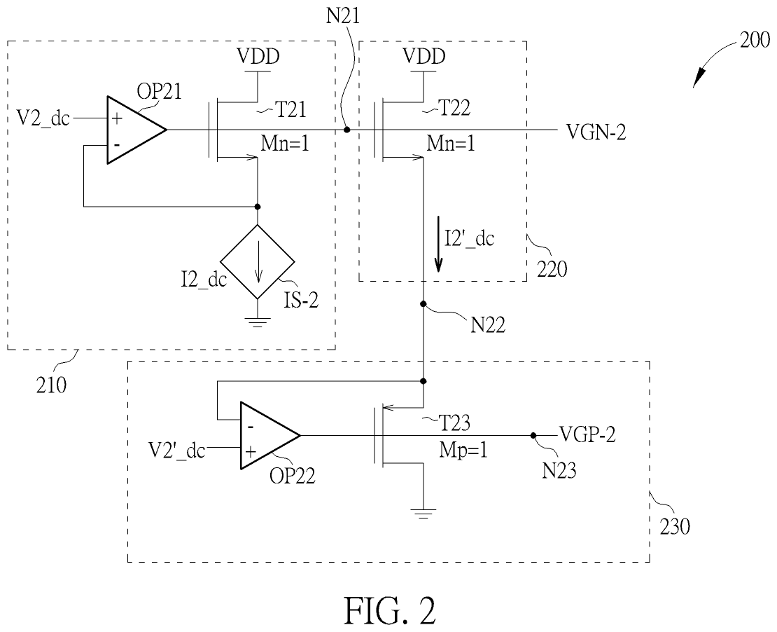

FIG. 2 is a diagram illustrating a bias voltage generating circuit 200 according to a second embodiment of the present invention. The bias voltage generating circuit 200 includes a first circuit subunit 210, a second circuit subunit 220, and a third circuit subunit 230. The first circuit subunit 210 is arranged to generate a bias voltage VGN-2 at a node N21 in response to a current I2_dc and an input voltage V2_dc. The second circuit subunit 220 is coupled to the first circuit subunit 210, and receives the bias voltage VGN-2 and generates a current I2′_dc flowing through a node N22, wherein the current I2′_dc is mirrored from the current I2_dc. The third circuit subunit 230 is coupled to the node N22, and generates a bias voltage VGP-2 at a node N23 in response to the current I2′_dc and an input voltage V2′_dc .

The first circuit subunit 210 includes an amplifier circuit OP21, a transistor T21, and a current source IS-2. The amplifier circuit OP21 has a non-inverting input terminal, an inverting input terminal, and an output terminal, wherein the non-inverting input terminal of the amplifier circuit OP21 receives the input voltage V2_dc. The transistor T21 has a first terminal coupled to the output terminal of the amplifier circuit OP21, a second terminal coupled to the inverting input terminal of the amplifier circuit OP21, and a third terminal coupled to a first voltage source. The transistor T21 may be an N-type MOSFET, wherein the first terminal of the transistor T21 may be a gate terminal of the N-type MOSFET, the second terminal of the transistor T21 may be a source terminal of the N-type MOSFET, and the third terminal of the transistor T21 may be a drain terminal of the N-type MOSFET. The first voltage source may be a voltage source providing the voltage VDD. The current source IS-2 may be arranged to provide the current I2_dc.

The gate terminal of the transistor T21 may be coupled to both the output terminal of the amplifier circuit OP21 and the node N21, and the node N21 may be further coupled to the second circuit subunit 220.

Assume that the amplifier circuit OP21 has a very large gain, and a relationship between the non-inverting terminal and the inverting terminal of the amplifier circuit OP21 is a virtual ground. As a result, a voltage at the inverting input terminal of the amplifier circuit OP21 is a voltage generated at the second terminal (e.g. the source terminal) of the transistor T21 in response to the current I2_dc and the input voltage V2_dc, and is equal to or substantially equal to the input voltage V2_dc.

The third circuit subunit 230 includes an amplifier circuit OP22 and a transistor T23. The amplifier circuit OP22 has a non-inverting input terminal, an inverting input terminal, and an output terminal, wherein the non-inverting input terminal of the amplifier circuit OP22 receives the input voltage V2′_dc. The transistor T23 has a first terminal coupled to the output terminal of the amplifier circuit OP22, a second terminal coupled to the inverting input terminal of the amplifier circuit OP22, and a third terminal coupled to a second voltage source. The transistor T23 may be a P-type MOSFET, wherein the first terminal of the transistor T23 may be a gate terminal of the P-type MOSFET, the second terminal of the transistor T23 may be a source terminal of the P-type MOSFET, and the third terminal of the transistor T23 may be a drain terminal of the P-type MOSFET. The second voltage source may be a voltage source providing the grounding voltage. The second terminal of the transistor T23 is coupled to the node N22. The first terminal of the transistor T23 is coupled to the node N23 for providing the bias voltage VGP-2.

Assume that the amplifier circuit OP22 has a very large gain, and a relationship between the non-inverting terminal and the inverting terminal of the amplifier circuit OP22 is a virtual ground. As a result, a voltage at the inverting input terminal of the amplifier circuit OP22 is equal to or substantially equal to the input voltage V2′_dc. For example, each of the amplifier circuits OP21 and OP22 may be an operational amplifier.

The input voltage V2_dc received by the first circuit subunit 210 may be the same as the input voltage V2′_dc received by the third circuit subunit 230. In addition, the current I2_dc provide by the current source IS-2 is generated through a bandgap circuit. As a result, the current I2_dc is a precise DC current.

The first circuit subunit 210 may be arranged to establish the stable current I2_dc at the second terminal of the transistor T21, and mirror the current I2_dc to the second circuit subunit 220. Since both the transistor T22 of the second circuit subunit 220 and the transistor T23 of the third circuit subunit 230 are coupled to the node N22, the mirrored current I2′_dc may flow through the transistors T22 and T23. In addition, the bias voltage generating circuit 200 may provide the bias voltages VGP-2 and VGN-2 to a power amplifier circuit (not shown in FIG. 2) through the nodes N23 and N21, respectively, for acting as bias voltage inputs and therefore providing stable bias voltages to the power amplifier circuit. Due to the stable voltages, another stable current may be mirrored within the power amplifier circuit in response to the current I2′_dc flowing through the transistors T22 and T23, and a current amplitude of the current inside the power amplifier circuit may be a multiple of the current I2′_dc, thereby generating the precise DC current required by the power amplifier circuit.

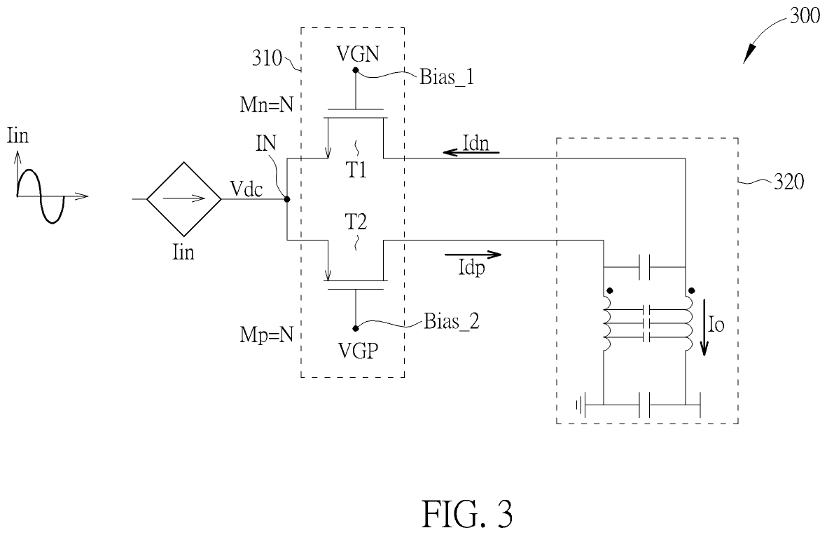

FIG. 3 is a diagram illustrating a power amplifier circuit 300 according to an embodiment of the present invention. The power amplifier circuit 300 includes a signal input terminal IN, bias voltage input terminals Bias_1 and Bias_2, an amplifying circuit 310, and a matching circuit 320. The signal input terminal IN is arranged to receive an input signal Iin, wherein the input signal Iin may be a current signal. The bias voltage terminals Bias_1 and Bias_2 are arranged to receive bias voltages VGN and VGP, respectively, wherein the bias voltage VGN may be the bias voltage VGN-1 generated by the bias voltage generating circuit 100 or the bias voltage VGN-2 generated by the bias voltage generating circuit 200, and the bias voltage VGP may be the bias voltage VGP-1 generated by the bias voltage generating circuit 100 or the bias voltage VGP-2 generated by the bias voltage generating circuit 200.

The amplifying circuit 310 is coupled to the input terminal IN, and arranged to receive the input signal Iin and generate currents Idn and Idp. The matching circuit 320 is coupled to the amplifying circuit 310, and arranged to match an output impedance of the power amplifier circuit 300 with an impedance of an antenna. In addition, the matching circuit 320 may be further arranged to combine the currents Idn and Idp to generate an output signal Io, wherein the output signal Io may be coupled to the antenna through a coupling circuit of the antenna.

The bias voltage input terminals Bias_1 and Bias_2 of the power amplifier circuit 300 may be coupled to corresponding nodes of the bias voltage generating circuit, respectively. For example, the bias voltage input terminal Bias_1 may be coupled to the node N13 of the bias voltage generating circuit 100 or the node N21 of the bias voltage generating circuit 200. The bias voltage input terminal Bias_2 may be coupled to the node N11 of the bias voltage generating circuit 100 or the node N23 of the bias voltage generating circuit 200.

In addition, the transistors T12 and T13 within the bias voltage generating circuit 100 or the transistors T22 and T23 within the bias voltage generating circuit 200 may be combined to form a mirror circuit, respectively, for mirroring the current I1′_dc or the current I2′_dc to the power amplifier circuit 300.

In response to the supply of the bias voltage VGN (i.e. the bias voltage VGN-1 or the bias voltage VGN-2) and the operations of the mirror circuit, the current Idn is generated in the power amplifier circuit 300. Similarly, in response to the supply of the bias voltage VGP (i.e. the bias voltage VGP-1 or the bias voltage VGP-2) and the operations of the mirror circuit, the current Idp is generated in the power amplifier circuit 300. The currents Idn and Idp are mirrored from the current I1′_dc flowing through the transistors T12 and T13 or the current I2′_dc flowing through the transistors T22 and T23.

The amplifying circuit 310 may be a push-pull amplifying circuit, and includes transistors T1 and T2, wherein the transistors T1 and T2 may be different types of transistors (e.g. the transistor may be an N-type MOSFET, and the transistor T2 may be a P-type MOSFET). The bias voltage VGN (i.e. the bias voltage VGN-1 generated by the bias voltage generating circuit 100 or the bias voltage VGN-2 generated by the bias voltage generating circuit 200) may be provided to a first terminal (e.g. a gate terminal) of the transistor T1, and the bias voltage VGP (i.e. the bias voltage VGP-1 generated by the bias voltage generating circuit 100 or the bias voltage VGP-2 generated by the bias voltage generating circuit 200) may be provided to a first terminal (e.g. a gate terminal) of the transistor T2.

In addition, a width of the transistor T1 may be designed to be greater than that of the transistor generating the corresponding bias voltage VGN-1 or VGN-2 in the bias voltage generating circuit (e.g. the transistor T13 or T22). For example, the width of the transistor T1 may be designed to be N times the width of the transistor T13 or T22 (e.g. Mn=N), wherein N is a positive integer. Similarly, a width of the transistor T2 may be designed to be greater than that of the transistor generating the corresponding bias voltage VGP-1 or VGP-2 in the bias voltage generating circuit (e.g. the transistor T12 or T23). For example, the width of the transistor T2 may be designed to be N times the width of the transistor T12 or T23 (e.g. Mp=N). It should be noted that there are many methods for designing transistors with different widths. For example, transistors with different widths can be directly configured in the circuit. As mentioned above, the width of the transistor T1 is designed to be N times the width of the transistor T13 or T22, and the width of the transistor T2 is designed to be N times the width of the transistor T12 or T23. In another example, transistors with the same width can be configured in the circuit, and the number of transistors connected in parallel is positively related to a multiple of the width. If the width of the transistor in the bias generating circuit is (1/N) times the width of the transistor in the corresponding power amplifier circuit, the power amplifier circuit can be implemented by coupling N transistors in parallel with the same width as the corresponding transistor in the bias generating circuit. As a result, “M” in Mn=1, Mp=1, Mn=N, and Mp=N represents multiple transistors, “n” or “p” represents the transistor type, and the value after the equal sign represents a multiple of the width or the number of transistors with the same width, wherein gate terminals, source terminals, and drain terminals of the N transistors with equal width coupled in parallel will be jointly coupled to a gate contact, a source contact, and a drain contact, respectively.

In this embodiment, the width of each the transistors T1 and T2 may be designed to be greater than that of the corresponding transistor in the bias voltage generating circuit, so that the amplifying mirror current effect can be achieved. For example, under a condition that the width of each of the transistors T1 and T2 is designed to be N times the width of the corresponding transistor in the bias voltage generating circuit, the currents Idn and Idp are N times the current I1′_dc or I2′_dc, respectively. If a current Idc is used to jointly represent the current I1′_dc flowing through the transistors T13 and T12 and the current I2′_dc flowing through the transistors T23 and T22, the relationship between the currents of the power amplifier circuit and the bias voltage generating circuit can be expressed as follows:

$$Idn = N * Idc ;$$

$$Idp = N * Idc ;$$

wherein both the currents Idn and Idp may be precise DC currents. Once the currents Idn, Idp as well as the bias voltages VGN and VGP are accurately controlled, the bias voltage Vdc can be naturally generated at the signal input terminal IN, wherein the bias voltage Vdc generated in the power amplifier circuit 300 may be equal to or substantially equal to the input voltage V1_dc/V2_dc of the bias voltage generating circuit.

By precisely controlling the voltage levels of the bias voltages Vdc, VGN, and VGP, the amplifying circuit 310 may be biased to operate in class A, class AB or deep A amplification. In addition, by precisely controlling these bias voltages, the power amplifier circuit 300 can achieve a better balance between linearity and amplification efficiency, and the effect of stabilizing the DC current of the power amplifier circuit can be achieved.

It should be noted that the present invention is not limited to applying the proposed bias voltage generating circuit to the power amplifier circuit shown in FIG. 3. The bias voltage generating circuit proposed by the present invention (e.g. the bias voltage generating circuit 100/200) can be applied to other power amplifier circuits for providing a corresponding bias voltage and causing the power amplifier circuit to generate a corresponding mirror current by the internal stable small DC current of the bias generating circuit 100/200, wherein the mirror current can be a relatively large and stable DC current.

In summary, the bias voltage generating circuit proposed by the present invention can utilize two input signals (e.g. the input voltage V1_DC/V2_DC and the input current I1_DC/I2_DC) to generate stable bias voltages and a stable DC current, and provide the stable bias voltages to a power amplifier circuit, so that the power amplifier circuit can be biased to operate in a specific type (e.g. class A, class AB, or deep A) of amplification. In addition, by the supply of the bias voltages, the power amplifier circuit can mirror a precise DC current, the power consumption of the power amplifier circuit can be effectively adjusted, and the same power amplifier circuit implemented by different chips can have similar performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bias voltage generating circuit, comprising:
a first circuit subunit, arranged to generate a first bias voltage at a first node in response to a first current and a first input voltage;
a second circuit subunit, coupled to the first circuit subunit, and arranged to receive the first bias voltage and generate a second current flowing through a second node, wherein the second current is mirrored from the first current; and
a third circuit subunit, coupled to the second node, and arranged to generate a second bias voltage at a third node in response to the second current and a second input voltage.

2. The bias voltage generating circuit of claim 1, wherein the first input voltage and the second input voltage are the same voltage.

3. The bias voltage generating circuit of claim 1, wherein the first circuit subunit comprises:
a first amplifier circuit, having a non-inverting input terminal, an inverting input terminal, and an output terminal, wherein the non-inverting input terminal receives the first input voltage;
a first transistor, having a first terminal coupled to the output terminal of the first amplifier circuit, a second terminal coupled to the inverting input terminal of the first amplifier circuit, and a third terminal coupled to a first voltage source; and
a current source, coupled to the second terminal of the first transistor, and arranged to supply the first current;
wherein the first terminal of the first transistor is further coupled to the first node.

4. The bias voltage generating circuit of claim 3, wherein in response to the first current and the first input voltage, a voltage generated at the second terminal of the first transistor is equal to or substantially equal to the first input voltage.

5. The bias voltage generating circuit of claim 3, wherein the second circuit subunit comprises:
a second transistor, having a first terminal coupled to the output terminal of the first amplifier circuit, a second terminal coupled to the second node, and a third terminal coupled to the first voltage source.

6. The bias voltage generating circuit of claim 5, wherein the third circuit subunit comprises:
a second amplifier circuit, having a non-inverting input terminal, an inverting input terminal, and an output terminal, wherein the non-inverting input terminal receives the second input voltage; and
a third transistor, having a first terminal coupled to the output terminal of the second amplifier circuit, a second terminal coupled to the inverting input terminal of the second amplifier circuit, and a third terminal coupled to a second voltage source, wherein the second terminal of the third transistor is coupled to the second node, and the first terminal of the third transistor is coupled to the third node.

7. The bias voltage generating circuit of claim 6, wherein the second transistor and the third transistor form a mirror circuit, and the mirror circuit is arranged to mirror the second current to a power amplifier circuit.

8. The bias voltage generating circuit of claim 7, wherein the first node is further coupled to a first bias voltage input terminal of the power amplifier circuit, and is arranged to supply the first bias voltage to the power amplifier circuit; and the third node is further coupled to a second bias voltage input terminal of the power amplifier circuit, and is arranged to supply the second bias voltage to the power amplifier circuit.

9. The bias voltage generating circuit of claim 8, wherein in response to supply of the first bias voltage, a third current is generated at the power amplifier circuit; in response to supply of the second bias voltage, a fourth current is generated at the power amplifier circuit; and both the third current and the fourth current are mirrored from the second current.

10. The bias voltage generating circuit of claim 9, wherein the third current flows through a first transistor of the power amplifier circuit, a width of the first transistor of the power amplifier circuit is greater than a width of the first transistor of the bias voltage generating circuit, the fourth current flows through a second transistor of the power amplifier circuit, and a width of the second transistor of the power amplifier circuit is greater than a width of the third transistor of the bias voltage generating circuit.

11. A bias voltage generating circuit, comprising:
a first circuit subunit, arranged to generate a first bias voltage at a first node in response to a first current and a first input voltage;
a second circuit subunit, coupled to the first circuit subunit, and arranged to receive the first bias voltage, and generate a second current flowing through a second node, wherein the second current is mirrored from the first current; and
a third circuit subunit, coupled to the second node, and arranged to generate a second bias voltage at a third node in response to the second current and a second input voltage;
wherein the first node is further coupled to a first bias voltage input terminal of a power amplifier circuit, and is arranged to provide the first bias voltage to the power amplifier circuit, and the third node is further coupled to a second bias voltage input terminal of the power amplifier circuit, and is arranged to provide the second bias voltage to the power amplifier circuit.

12. The bias voltage generating circuit of claim 11, wherein the first input voltage and the second input voltage are the same voltage.

13. The bias voltage generating circuit of claim 11, wherein the first circuit subunit comprises:
a first amplifier circuit, having a non-inverting input terminal, an inverting input terminal, and an output terminal, wherein the non-inverting input terminal receives the first input voltage;
a first transistor, having a first terminal coupled to the output terminal of the first amplifier circuit, a second terminal coupled to the inverting input terminal of the first amplifier circuit, and a third terminal coupled to a first voltage source; and
a current source, coupled to the second terminal of the first transistor, and arranged to supply the first current;
wherein the first terminal of the first transistor is further coupled to the first node.

14. The bias voltage generating circuit of claim 13, wherein in response to the first current and the first input voltage, a voltage generated at the second terminal of the first transistor is equal to or substantially equal to the first input voltage.

15. The bias voltage generating circuit of claim 13, wherein the second circuit subunit comprises:
a second transistor, having a first terminal coupled to the output terminal of the first amplifier circuit, a second terminal coupled to the second node, and a third terminal coupled to the first voltage source.

16. The bias voltage generating circuit of claim 15, wherein the third circuit subunit comprises:
a second amplifier circuit, having a non-inverting input terminal, an inverting input terminal, and an output terminal, wherein the non-inverting input terminal receives the second input voltage; and
a third transistor, having a first terminal coupled to the output terminal of the second amplifier circuit, a second terminal coupled to the inverting input terminal of the second amplifier circuit, and a third terminal coupled to a second voltage source, wherein the second terminal of the third transistor is coupled to the second node, and the first terminal of the third transistor is coupled to the third node.

17. The bias voltage generating circuit of claim 16, wherein in response to supply of the first bias voltage, a third current is generated at the power amplifier circuit; in response to supply of the second bias voltage, a fourth current is generated at the power amplifier circuit; and both the third current and the fourth current are mirrored from the second current.

18. The bias voltage generating circuit of claim 17, wherein the third current flows through a first transistor of the power amplifier circuit, a width of the first transistor of the power amplifier circuit is greater than a width of the first transistor of the bias voltage generating circuit, the fourth current flows through a second transistor of the power amplifier circuit, and a width of the second transistor of the power amplifier circuit is greater than a width of the third transistor of the bias voltage generating circuit.

19. The bias voltage generating circuit of claim 18, wherein the first bias voltage is provided to a first terminal of the first transistor of the power amplifier circuit, and the second bias voltage is provided to a first terminal of the second transistor of the power amplifier circuit.

20. The bias voltage generating circuit of claim 11, wherein the first current is equal to or substantially equal to the second current.
